(19) United States
(12) Patent Application Publication
(10) Pub. No.: US 2013/0202809 A1
(43) Pub. Date: Aug. 8, 2013

(54) METHODS OF FORMING LAYERS

(71) Applicant: SEAGATE TECHNOLOGY LLC, Cupertino, CA (US)

(72) Inventor: Philip George Pitcher, Shakopee, MN (US)

(73) Assignee: SEAGATE TECHNOLOGY LLC, Cupertino, CA (US)

(21) Appl. No.: 13/756,672

(22) Filed: Feb. 1, 2013

Related U.S. Application Data
(60) Provisional application No. 61/594,542, filed on Feb. 3, 2012.

(51) Int. Cl. C23C 14/48

(52) U.S. Cl. CPC C23C 14/48
USPC 427/523

(57) ABSTRACT

A method of forming a layer, the method including providing a substrate having at least one surface adapted for deposition thereon; providing a precursor ion beam, the precursor ion beam including ions; neutralizing at least a portion of the ions of the precursor ion beam to form a neutral particle beam, the neutral particle beam including neutral particles; and directing the neutral particle beam towards the surface of the substrate, wherein both the ions and the neutral particles have implant energies of not greater than 100 eV, and the neutral particles of the particle beam form a layer on the substrate.

### PRIORITY

This application claims priority to U.S. Provisional Application No. 61/594,542 entitled “NANOPROCESING AND THIN FILM PROCEESING WITH NEUTRAL PARTICLES”, having docket number STL17112.01 filed on Feb. 3, 2012, the disclosure of which is incorporated herein by reference thereto.

### BACKGROUND

In many thin film applications, surfaces upon which layers are to be formed may include several different materials, some electrically insulating and some electrically conducting; and/or several different topographies. Such surfaces can influence charging effects of the surface and thereby cause different and perhaps unknown interactions with an incoming particle beam containing charged particles. Currently utilized processes merely compensate for the charged particles making up the beam by combining an electron beam with the ion beam, thereby seeking to have a net charge of zero.

### SUMMARY

A method of forming a layer, the method including providing a substrate having at least one surface adapted for deposition thereon; providing a precursor ion beam, the precursor ion beam including ions; neutralizing at least a portion of the ions of the precursor ion beam to form a neutral particle beam, the neutral particle beam including neutral particles; and directing the neutral particle beam towards the surface of the substrate, wherein the neutral particles have implant energies of not greater than 100 eV, and the neutral particles of the particle beam form a layer on the substrate.

A method of forming a layer, the method including providing a substrate having at least one surface adapted for deposition thereon; providing a precursor ion beam, the precursor ion beam including ions; neutralizing at least a portion of the ions of the precursor ion beam to form a modified precursor particle beam by directing the precursor ion beam towards an ion optic grid; and directing the modified precursor particle beam towards a high aspect ratio grid to form a neutral particle beam; and directing the neutral particle beam towards the surface of the substrate, wherein the neutral particles have implant energies of not greater than 100 eV, and the neutral particles of the particle beam form a layer on the substrate.

A method of forming a layer, the method including providing a substrate having at least one surface adapted for deposition thereon; providing a precursor ion beam, the precursor ion beam including ions; directing the precursor ion beam towards mass selection techniques to form a modified precursor particle beam; and directing the modified precursor particle beam towards a high aspect ratio grid to form a neutral particle beam; and directing the neutral particle beam towards the surface of the substrate, wherein the neutral particles have implant energies of not greater than 100 eV, and the neutral particles of the particle beam form a layer on the substrate.

The above summary of the present disclosure is not intended to describe each disclosed embodiment or every implementation of the present disclosure. The description that follows more particularly exemplifies illustrative embodiments. In several places throughout the application, guidance is provided through lists of examples, which examples can be used in various combinations. In each instance, the recited list serves only as a representative group and should not be interpreted as an exclusive list.

### BRIEF DESCRIPTION OF THE FIGURES

FIG. 1A shows a schematic illustration of an exemplary system; and FIG. 1B shows a closer view of a portion of the system shown in FIG. 1A.

FIG. 2 is a graph of beam divergence (°) versus the bias of the third grid of an ion optic grid in a specific exemplary system.

FIG. 3 shows a schematic of an exemplary disclosed system.

FIG. 4 illustrates how surface implantation can modulate surface density through insertion and displacement effects.

FIG. 5 shows beam expansion of an exemplary molecular ion.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

In the following description, reference is made to the accompanying set of drawings that form a part hereof and in which are shown by way of illustration several specific embodiments. It is to be understood that other embodiments are contemplated and may be made without departing from the scope or spirit of the present disclosure. The following detailed description, therefore, is not to be taken in a limiting sense.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the properties sought to be obtained by those skilled in the art utilizing the teachings disclosed herein.

The recitation of numerical ranges by endpoints includes all numbers subsumed within that range (e.g. 1 to 5 includes 1, 1.5, 2, 2.75, 3, 3.80, 4, and 5) and any range within that range.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

“Include,” “including,” or like terms means encompassing but not limited to, that is, including and not exclusive. It should be noted that “top” and “bottom” (or other terms like “upper” and “lower”) are utilized strictly for relative descriptions and do not imply any overall orientation of the article in which the described element is located.

“Layer” as utilized herein can refer to material on the surface of a substrate, material at the interface of the substrate (i.e. materials partially implanted into the surface but also exposed as if on the surface), material within the substrate (i.e. materials implanted into the substrate and not exposed at the surface of the substrate), or any combination thereof Formation of a layer can therefore include implantation of the material in the bulk of the substrate (typically only to a depth of a few nanometers or less below the surface); implantation of the material at the surface of the substrate (e.g., partially embedded in the substrate); deposition of the material on the surface of the substrate (or on material that has already been formed by a disclosed method); or combinations thereof. It should also be noted that as a layer is formed, the surface is continuously moving upward away from the substrate. A “film” as utilized herein can refer to material that exists on the surface of the substrate. A layer may therefore include only a film or a film and material within the substrate. Methods disclosed herein can be utilized to form layers. The formation of layers utilizing disclosed methods can include surface modification, materials synthesis, compositional modifications, or combinations thereof Formation of layers, as disclosed herein can include process interactions that may be confined to surface layer atoms or to within a few bond lengths from the surface. Formation of layers utilizing disclosed methods can also be referred to as surface sub-plantation (SSP).

Disclosed herein are methods, processes, and systems to extend and improve surface nanoengineering technologies. Disclosed methods offer surface sub-plantation (SSP) and interfacial engineering for example using various methods and techniques including neutral particle beams. In disclosed methods and systems, processing occurs at depth scales ranging from sub-monolayer to a few bond lengths from the surface. Applications include surface modification, materials synthesis, and compositional modifications on a depth scale extending a few nanometers from the surface, etching and interfacial engineering. Both carbon and hydrogenated carbon layers are specifically discussed herein, but the disclosed methods and considerations are applicable to other materials, including metastable surface compositions or surface layers. One of skill in the art, having read this specification, will understand that the disclosed methods are applicable to materials other than carbon and hydrogenated carbon.

In many important thin film applications, such as for example slider transducer technology in data storage, microelectronics, or biomedical applications, surfaces may include several different materials, some electrically insulating, some semiconducting, some electrically conducting (which may be grounded to electrically floating structures for example) on scales ranging from below sub-micron to centimeter. There may also be film topography and/or structures located near edges. All of these factors, as well as others, may influence charging effects. Charging or differential charging of insulating and/or conducting surfaces can affect incident charged particle flux, energy and arrival angle distributions, any or all of which may be detrimental to surface nanoengineering processes.

Furthermore, many ion beams and plasma based processes involve a plasma-surface interaction. When any surface is in contact with plasma, a sheath is formed over the surface that can affect the flux, energy and incidence angle distributions of charged particles crossing the sheath boundary. In a uniform incident charged particle flux over a flat, homogeneous, semi-infinite substrate surface the sheath thickness is uniform and its electric field lines are normal to the substrate surface, i.e., the sheath is one dimensional in nature as will be the charged particle flow across it. A distortion of the sheath field can concomitantly affect the flux, energy and angular distribution of particles incident at the materials interface. Several factors can produce plasma sheath distortion. Examples can include the interface between insulating and conducting materials. Even in planar geometries, differences in sheath thickness can result from differences in sheath potential developed on either side of the interface (the insulator attaining the floating potential for given plasma characteristics, the conductor potential could be variable e.g. through biasing, etc.). The resulting potential difference across the interface can locally distort the electric field from the surface normal direction and hence the ion flow across it. Topographic features and substrate/wafer edges can also distort the plasma sheath. The extent of distortion is dependent on the relative size of the sheath thickness to the length scale of the topographic features and becomes significant when the sheath width is comparable or smaller than the feature size with concomitant distortion of the incident charged particle flux, energy and angular distributions.

Because of the above issues, charging effects of the surface and plasma-surface interactions, the current disclosure utilizes a neutral particle beam to interact with the surface. Use of a neutral beam eliminates the interactions with the plasma sheath (or even minimizes the formation of the plasma sheath) and may minimize or even prevent the creation of a voltage, or charge on the surface of substrates and formed layers. This can be advantageous because such voltages can be problematic for certain applications. For example, tunneling magnetoresistive (TMR) heads can be detrimentally affected by the formation of a charge during fabrication. Furthermore, if a charge is not formed on the surface during formation of the layers, the particles forming the layer can be more reliably controlled. This can afford the fabrication of layers that have more uniform properties.

Conventional deposition, etch and implantation processes control particle characteristics and particle transport using electrostatic and/or electromagnetic interactions with charged process particles. Methods to neutralize surface charge at a substrate include beam pulsing and flooding by electron beam irradiation. The former relies on surface diffusive dissipation of charge between pulses and the latter by achieving a surface charge balance upon recombination. A more common, practicable prior art method to attempt to reduce charge effects at the substrate is by “coupling” electrons (for positive ion beams for example) to an ion beam through an e-beam source or for example through a plasma bridge neutralizer. However, little recombination of the ions and the electrons occurs during beam transport and the situation is one of “balancing” the quantities of opposite charges (particles) arriving at the substrate. As such, previously utilized neutralized ion beam processing has similarities to that of processing with a plasma beam (discussed above). Consequently, charge effects may not be entirely eliminated in previously utilized processes and systems.

Disclosed methods and systems on the other hand utilized highly controlled, low energy beams of neutral particles that subsequently interact with a substrate as true neutral particles. This can eliminate or at the very least reduce the detrimental interactions discussed above. Generally, disclosed methods seek to create a charged particle beam wherein the particles have the desired properties and then neutralize the particles without detrimentally altering the properties of the particles.

Disclosed methods can generally include the steps of providing a substrate; providing a precursor ion beam; forming a neutral particle beam; and directing the neutral particle beam towards the substrate to form a layer.

Providing a Substrate

Providing a substrate can be accomplished by placing, configuring, or otherwise locating a substrate within a system, for example. The substrate upon which the layer is to be formed can be any type of material or structure. In some embodiments, an exemplary substrate can have at least one surface upon which the layer formation will take place. Such a surface can be referred to as “being adapted for layer formation”, which can include simply being placed in a process chamber so that a layer will be formed on at least the desired surface. In some embodiments, the substrate can include structures or devices formed thereon or therein. In certain embodiments, methods disclosed herein can be utilized to form overcoats on various structures; and in such embodiments, the device upon which the overcoat is to be formed can be considered the substrate.

Precursor Ion Beam

Disclosed methods also include a step of providing, creating, or otherwise obtaining a precursor ion beam. A precursor ion beam includes ions or charged particles that may have desired properties. Once the ion beam is neutralized, the neutral particles, formerly charged particles or ions, still have the desired properties. The desired properties can include, for example, energy, velocity, angular divergence distribution, and combinations thereof. In some embodiments, ions in a precursor ion beam can have one or more property selected so that neutralized versions thereof have desired properties. The charged particles can either be positively or negatively charged. One of skill in the art, having read this specification, can adapt the more specifically discussed concepts that may be discussed specifically with respect to positively charged ions for the use of negatively charged ions.

Providing a precursor ion beam may be accomplished by utilizing commercially available equipment. For example, broad beam ion sources, or narrow beam ion sources can both be utilized. Examples of types of sources of precursor ion beams can include, for example, an inductively coupled RF ion source, and direct current (DC) broadbeam ion sources.

Neutralizing the Precursor Ion Beam

After the precursor ion beam is formed, the precursor ion beam is then neutralized. This step (which may or may not be carried out in multi-step fashion) changes the ions of the precursor ion beam to neutral particles of a neutral particle beam. The phrase “neutralizing the ions of the precursor ion beam” (and/or similar phrases) generally implies that at least some of the ions have been neutralized. Therefore, as used herein, the phrase neutralized particle beam refers to a particle beam in which at least some of the ions of a precursor ion beam have been neutralized. As such, a neutralized particle beam includes a partially neutralized particle beam and a fully neutralized particle beam. In some embodiment, substantially all the ions have been neutralized. In some embodiments, at least about 5% of the ions have been neutralized. In some embodiments, at least about 20% of the ions have been neutralized. In some embodiments, at least about 50% of the ions have been neutralized. In some embodiments, at least about 75% of the ions have been neutralized. In some embodiments, at least about 95% of the ions have been neutralized. In some embodiments, about 100% of the ions have been neutralized.

In some embodiments, a precursor ion beam can be neutralized using surface neutralization techniques. Such surface neutralization techniques can be set up to largely preserve the energetic and directional characteristics of the incident ion beam(s) (the “desired properties”) allowing the generation of highly controlled beams of neutral particles from a pre-conditioned, precursor ion beam.

For example, one way of neutralizing the ions can involve directing a beam of charged particles at a surface, for example a metal surface. Ions approaching a surface can be neutralized by, for example, resonant or Auger effects. If ions closely approach the surface at grazing incidence, the kinematics of the scattering process will result in low angle (near specular) forward scattering with very low kinetic energy loss, producing neutral particles whose energy and directionality (i.e., “desired properties”) are close to that of the incident ion beam. Neutralization of a precursor ion beam using such grazing collisions can be made more difficult or less functional by factors such as surface roughness and the presence of surface contaminants.

Alternatively, neutral particles can be produced from a precursor ion beam by ion extraction from a plasma boundary with direct ion injection into a high aspect ratio grid. In such a case, neutralization occurs through sidewall interactions as ions travel through the high aspect ratio holes of a grounded grid. Previous methods have attempted such control, but have shown limited control over producing grazing, neutralizing collisions because of the poorly controlled interaction of the plasma meniscus boundary with the grid orifices, which determines the shape, and thereby directionality of ions emitting from the surface of the meniscus. Furthermore, source gas pressure may result in charge-exchange collisions between fast ions and slow neutrals which can mitigate the quality of the beam e.g., through its broadened energy distribution and reduce neutral content.

In some embodiments, disclosed systems and methods therefore utilize ion optics to control the glancing sidewall collisions and thereby improve control over the ion to neutral conversion process. In some embodiments, a four grid system can be utilized. For example, with a broadbeam ion source, a high aspect ratio grid could form a fourth grid supplementing a typically utilized three grid system in disclosed methods and systems.

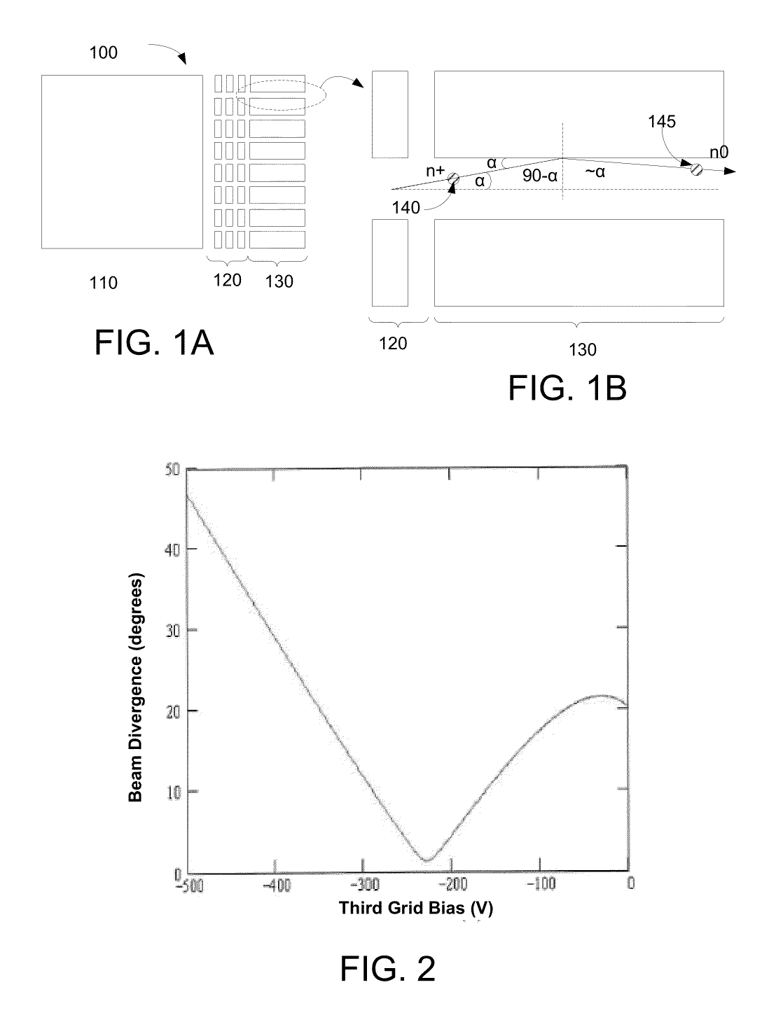

A schematic of an exemplary system can be seen in FIG. 1A. The system exemplified in FIG. 1A is an example of a broad beam ion source system. The system 100 seen in FIG. 1A includes an ion source 110 (to provide the precursor ion beam). The ion source 110 can include, for example, a broad beam ion source, or a narrow beam ion source. A specific example of an ion source is an inductively coupled RF ion source. The system can also include components to neutralize the ions, for example ion optic grid 120 and high aspect ratio grid 130. Ion optic grid 120 can include commonly utilized ion optical systems for example. Ion optic grid 120 generally includes three sets of grids, a first grid, a second grid, and a third grid, with the first grid being the one closest to the ion source and the third grid being the one farthest from the ion source. In ion optic grids 120 utilized in disclosed methods or systems, the third grid is electrically biased, not grounded as it is in prior art systems. The system 100 can also include a high aspect ratio neutralizing grid 130. The high aspect ratio neutralizing grid can either be grounded or biased. The bias potential of the third grid can control the angle of injection of ions into the high aspect ratio neutralizing grid.

FIG. 2 shows a specific illustrative example for a given set of source, beam, and grid geometry and biasing parameters, showing how variation of ion optical parameters, for example, of the third grid bias potential can be used to significantly affect the angle of injection of ions into the high aspect ratio grid 130. It should be noted that many factors determine the ultimate divergence limit of the beam. In this particular illustrative example, it can be seen that relative to a three grid system with grounded third grid optics that is operated to produce a divergent beam with divergence of around 20 degrees, a large window of third grid bias is available to reduce the beam divergence. A relatively narrow window of third grid bias exists that would produce a low beam divergence (less than about 5 degrees) to produce a directly corresponding grazing angle sidewall incidence in the high aspect ratio grid to produce a neutral particle beam.

The biased third grid of the ion optic grid can function to provide a much less divergent beam of particles for entry into the high aspect ratio grid 130. It does this through the action of its electrostatic field on the charged beam particles. Concomitantly, the particles strike the plates of the high aspect ratio grid at a lower incidence, and therefore stay the same (i.e., retain their “desired properties”) as they were formed or altered to. This can be advantageous because it produces a more controlled beam of particles having the desired properties.

Once the precursor ion beam has gone through the ion optic grid it can be referred to as a modified precursor ion beam. A modified precursor ion beam can then be directed through the high aspect ratio grid. It should be noted that a precursor ion beam and/or a modified precursor ion beam can be directed through other components and/or have other steps carried out thereon before and/or after being directed through an ion optic grid. It should also be noted that systems can include more than one ion optic grid or different ion optical components in some embodiments.

FIG. 1B shows an enlarged portion of the third grid of the ion optic grid 120 and the high aspect ratio neutralizing grid 130. As seen there, the beam divergence (α) and side wall glancing angle (90-α) with respect to normal. Also illustrated in FIG. 1B is a charged (n⁺) particle 140 before it strikes the sidewalls of the high aspect ratio neutralizing grid 130 and after it strikes the sidewalls, thereby becoming a neutral (n0) particle 145.

For a beam, having a given divergence and diameter, the geometrical considerations of the aspect ratio of the grid can be set to affect the desired degree of glancing interactions of beam particles with the wall (in terms of the fraction of beam particles that strike the wall and the number of times a particle will interact with the wall during transport through it) and therefore the degree of neutralization (or alternatively ionization) of the beam as it exits the high aspect ratio neutralizing grid 130.

Directing Neutral Particle Beam at Substrate

After the precursor ion beam is neutralized to form the neutral particle beam, the neutral particle beam is then directed at the substrate. Generally, components such as an ion source, ion optic grid, a high aspect ratio grid and optionally a substrate holder (or simply the substrate) can be configured within a system so that the ions, and eventually the neutral particles interact with the substrate. One of skill in the art, having read this specification, will understand how such a system should be configured. It should be noted that for a partially neutralized beam, beam divergence can be exhibited by the beam (with probable loss of process control) if proper consideration of the “throw” distance to the substrate table is not made in instrument design together with proper control of deposition rate in the process window.

To Form a Layer

Disclosed methods can be utilized to form layers of any material; or stated another way neutral particles that are inserted into a surface layer can have any identity. In some embodiments, disclosed methods can be utilized to form layers that include carbon. In some embodiments, disclosed methods can be utilized to form layers that include carbon as a hydrocarbon (e.g., hydrogenated carbon). It should be understood however that carbon and hydrocarbons are simply an example and disclosed methods are not limited to formation of carbon and/or hydrocarbon layers or films.

As discussed above, “layer” as utilized herein can refer to material on the surface of a substrate, material at the interface of the substrate (i.e. materials partially implanted into the surface but also exposed as if on the surface), material within the substrate (i.e. materials implanted into the substrate and not exposed at the surface of the substrate), or any combination thereof. Formation of a layer can therefore include implantation of the material in the bulk of the substrate (typically only to a depth of a few nanometers or less below the surface); implantation of the material at the surface of the substrate (e.g., partially embedded in the substrate); deposition of the material on the surface of the substrate (or on material that has already been formed by a disclosed method); or combinations thereof It should also be noted that as a layer is formed, the surface is continuously moving upward away from the substrate. A “film” as utilized herein can refer to material that exists on the surface of the substrate. A layer may therefore include only a film or a film and material within the substrate. Methods disclosed herein can be utilized to form layers. The formation of layers utilizing disclosed methods can include surface modification, materials synthesis, compositional modifications, or combinations thereof Formation of layers, as disclosed herein can include process interactions that may be confined to surface layer atoms or to within a few bond lengths from the surface. Formation of layers utilizing disclosed methods can also be referred to as SSP.

The material making up the neutral particle beam will be a component of the material of the layer to be formed. In some embodiments, materials from the neutral particle beam will be inserted into a substrate, in which case a mixture of the material from the neutral particle beam and the substrate material will be formed. In some embodiments, layers containing carbon (for example) are formed. In some other embodiments, layers containing hydrogenated carbon (both carbon and hydrogen) are formed. Layers that are formed can have various thicknesses. The thickness of a layer, as that phrase is utilized herein, refers to a measure of the thickness. For example, a measure of a thickness may provide an average thickness, or may provide a property that can be related to the thickness or the average thickness of the layer. For example, layers can be from about sub-monolayer (less than a monolayer of the material) to about 30 Å thick. In some embodiments layers can be from about 15 Å to about 25 Å thick; and in some embodiments, layers can be from about 15 Å to about 20 Å thick.

Disclosed methods can be utilized to engineer the composition of a layer. For example, disclosed methods can be utilized to engineer a carbon containing layer (it is noted that a carbon containing layer is utilized as an example only and compositional engineering can be undertaken with any type of material). It is also noted that compositional engineering can be utilized to form a carbon containing layer and/or a hydrogenated carbon containing layer. Application of disclosed processes or methods to the deposition of carbon containing layers can allow the sp3/sp2 ratio of the layer to be engineered. “sp3” and “sp2” refer to types of hybridized orbitals that a carbon atom (for example) may contain. An sp3 carbon atom is bonded to four other atoms, such as four other carbon atoms because it contains four sp3 orbitals, a sp3 orbital forms a very strong σ bond to another carbon atom for example. An sp2 carbon atom is bonded to three other atoms, such as three other carbon atoms because it contains three sp2 orbitals, a sp2 orbital forms a π bond that is weaker than a σ bond. In numerous applications, including carbon overcoats that are used in magnetic recording heads and media, carbon having more sp3 than sp2 bonds can often be desired because the carbon is more stable (i.e., it contains stronger bonds). In some embodiments, disclosed processes or methods can allow formation of a carbon containing layer that is more stable, i.e., has more sp3 bonds than sp2 bonds. Such carbon layers can have higher thermal resiliency, better mechanical properties, better chemical characteristics, or combinations thereof.

As discussed above, a layer can refer to material on the surface of a substrate, material at the interface of the substrate (i.e. materials partially implanted into the surface but also exposed as if on the surface), material within the substrate (i.e. materials implanted into the substrate and not exposed at the surface of the substrate), or any combination thereof. In embodiments, methods disclosed herein do not form layers based on nucleation growth mechanisms. Nucleation growth mechanisms fundamentally limit the minimum thickness of a continuous film.

Some disclosed methods include processing or depositing low energy particles in order to minimize the undesired effects of implantation. The following construct can be utilized herein in order to explain the energy of the particles. In the exemplary case of a grounded beam particle source, the incident energy (V_{inc}) of a particle immediately prior to its interaction with an unbiased, uncharged substrate surface is given by the sum of the beam voltage (or screen bias), V_{b}, and the plasma potential, Vₚ, assuming the incident particle is a monoatomic, singly charged ion. In this instance, the implant energy (Vᵢₘₚ) is the same as the incident energy (V_{inc}) as described. For the case of a singly charged molecular ion or cluster, it is assumed that upon interaction with atoms at the substrate surface, molecular orbital overlap results in complete fragmentation of the molecule (or cluster) into its component atomic species. The incident kinetic energy (V_{b}+Vₚ) minus the molecular or cluster dissociation energy is then partitioned over each atomic “fragment” according to its mass fraction (mass_{atomic component}/mass_{total molecule or cluster}) of the original incident molecular or cluster mass to give Vᵢₘₚ of each fragment.

The implant energy of a particle can be selected (the maximum is selected) to restrict the ion projected range into the surface to less than a maximum of a few bond lengths. The implant energy of a particle can also be selected (the minimum is selected) to be at least sufficient to allow penetration of the surface energy barrier to allow incorporation of the particles into the surface. Because of the minimum energy selected (enough to allow penetration of the particle into the substrate), growth of the layer is not accomplished via typical nucleation growth mechanisms. The chosen range of implant particle energies being such that kinematic energy transfer to target atoms is either insufficient to produce displacement or, on average, to generally produce only one or two displacement reactions or sufficient to allow insertion into the surface or to distances within a few bond lengths from the surface.

The particles, once contacted with the surface of the substrate may fragment into smaller particles. In such instances, the particles themselves, the fragments of such incident particles or some combination thereof may have energies, i.e., implant energies of not greater than 100 eV. When implant energies are discussed herein, it should be understood that such energies can refer to incident particles, fragments of such incident particles produced by their interaction with the surface or any combination thereof. In some embodiments, disclosed methods include utilizing particles having implant energies of tens (10 s) of electron volts (eV). In some embodiments, methods include utilizing particles having implant energies of less than about 100 eV. In some embodiments, methods include utilizing particles having implant energies of not greater than about 80 eV. In some embodiments, methods include utilizing particles having implant energies of not greater than about 60 eV. In some embodiments, methods include utilizing particles having implant energies of not greater than about 40 eV. In some embodiments, methods include utilizing particles having implant energies of not greater than about 20 eV. In some embodiments, methods include utilizing particles having implant energies from about 20 eV to about 100 eV. In some embodiments, methods include utilizing particles having implant energies from about 20 eV to about 80 eV. In some embodiments, methods include utilizing particles having implant energies from about 20 eV to about 60 eV. In some embodiments, methods include utilizing particles having implant energies from about 20 eV to about 40 eV.

Disclosed methods can change the fundamental growth mechanism from nucleation, which relies on surface mobility effects. Nucleation based methods are typical in processes that utilize incident energies that are less than about 20 eV (e.g., typical sputter deposition methods are from about 7 to about 15 eV; and evaporation methods are less than about 1 eV). Disclosed methods suppress mobility by implantation into a near surface region. The implanted region is kept shallow in order to produce ultrathin altered surface regions. To accomplish this, low energy incident particles, which are difficult in practice to produce at usable beam fluxes, are utilized. Conventional low energy implantation still utilizes particles having KeV energies in order to achieve commercially viable beam currents. The particles utilized are relatively large molecules or clusters so that the fragments have low energies; e.g., silicon doping. For functional engineering of nm scale films, this fragmentation process does not allow sufficient control. Disclosed methods therefore utilize very low incident energies with partitioning over small molecules to achieve controllable, very low implant energy particles.

Process control of particle energy, beam current, beam divergence, charge state and ion mass are typically static in conventional process techniques. However variation of selected beam parameters may be used to e.g. tailor interfaces, compositional or damage center concentration profiles with and without sample goniometric motions. In conjunction, variably doped multilayer nanostructures or selective depth or surface doping may be achieved by appropriate switching of the mass filter parameters during or post-film growth e.g. in lube engineering applications.

Optional Steps

Disclosed methods can also include other, optional steps. Such optional steps can improve low energy processing techniques utilizing various techniques. Such optional steps can also be utilized to provide the ions with the above discussed “desired properties”. In some embodiments where such optional steps are utilized to give the ions/neutral particles desired properties, they are generally undertaken before the ions are directed through the high aspect ratio grid. Once the ions are neutralized, control and therefore property modification can be difficult, if not impossible.

One example of an optional step is the acceleration and/or deceleration of ions, which can be referred to herein as “ion accel-decel” approaches. Such optional methods and/or steps can be undertaken before the particle beam is neutralized. Such ion accel-decel approaches can be accomplished with mass selection, beam conditioning and shaping in conjunction with goniokinematic processing (coordinated real time variation of particle beam parameters with the goniometric (angle) disposition of the target process surface (with respect to the beam axis)) to control factors that afford control of process phenomena, for example etch, interfacial nanoengineering, nanodoping, surface nanoengineering of nanomaterials and metastable surface materials. Ion accel-decel approaches can circumvent low energy ion beam transport effects and poor ion source performance characteristics at low energies (e.g. unusably low beam currents) to improve process control. Ions can be accelerated and conditioned at high energies and then decelerated to impact energy just prior to collision with a substrate. The existence limits for low energy processes can, however, be extremely narrow and easily corrupted.

In another embodiment, the beam may be optionally shaped. Shaping of the beam could occur e.g. at the ion source or e.g. after mass selection. In some embodiments, a narrow rectangular or line shaped beam can be an advantageous shape. Another advantageous aspect is that the neutral particle beam itself is static and the substrate can be scanned mechanically with respect to the beam. Both shaping, static incidence and independent substrate scanning are important aspects in kinogoniometric neutral particle processing.

Exemplary Systems

Both methods and systems are disclosed herein. Generally, disclosed systems can be configured by obtaining components that carry out one or more of the disclosed method steps. In some embodiments, a disclosed system can include an ion source, an ion optic grid, and a high aspect ratio grid. In some embodiments, a system can also include an optional substrate holder. Similarly, some disclosed systems can optionally include components to affect ion accel-decel, mass selection, beam shaping, beam scanning, beam pulsing, or various combinations thereof.

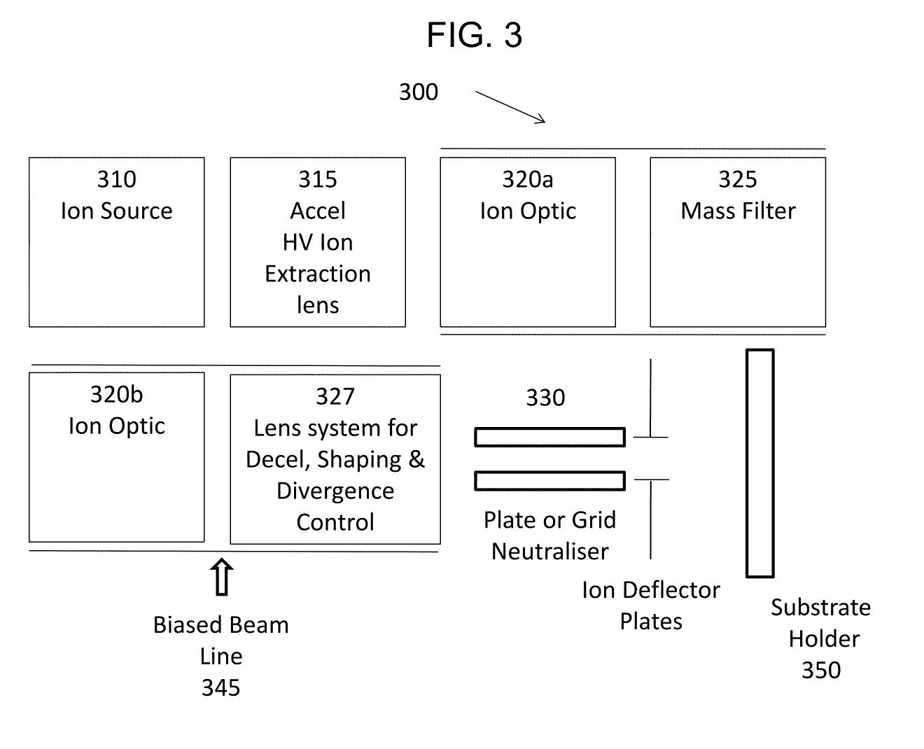

A schematic illustration including exemplary, basic elements, but not detailed components of an exemplary system or a disclosed system that can be utilized to carry out disclosed methods can be seen in FIG. 3. The exemplary system 300 seen in FIG. 3 includes an ion source 310, which can be a gas and/or solids ion source for example and can be biased (+ve) to the ion impact potential (Floating); two ion optic components 320a and 320b, which in this case are exemplified as ion-optical lenses; and a high aspect ratio grid 330. This exemplary system also includes optional components: a high voltage (HV) ion extraction lens 315, a mass filter 325, a beam decel and shaper ion-optical assembly 327, and a substrate holder 340. The biased beam line 345 can be used to allow proper beam transport of the ions through the system.

In this disclosed system, to overcome beam transport difficulties arising from space-charge expansion, low energy ions are extracted (via 315) and accelerated from an ion source (310) which is biased at the desired target (substrate) impact potential and transported through a biased beam line 345 assembly to control space-charge expansion effects during beam transport. After mass filtering (via 325) the ions are deaccelerated (via 327) back to the impact potential and the controlled, low divergence angle beam is injected into a high aspect ratio neutralizing device (330). The resultant beam of neutral particles (atoms, molecules, or nanoclusters) effectively retaining the energy and directionality of the precursor ion beam, is then directed at the substrate (340). An optional set of ion deflector plates may also be situated after the high aspect ratio neutralizing device before the substrate assembly. Such ion deflector plates may be e.g. electrostatically charged to deflect any ionized particles from the beam path.

Advantages/Effects

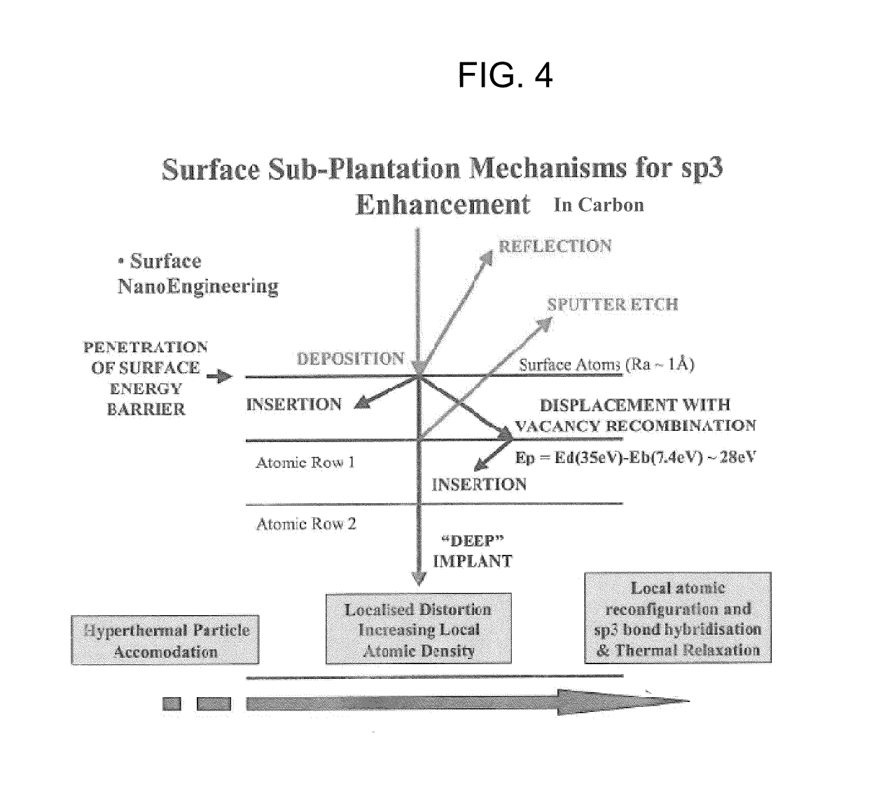

Disclosed methods strive to confine the processing effects to the top few bond lengths of the layer continuously, as growth proceeds. This can minimize or eliminate the effects of non-linear atomic interaction of implanting particles with substrate atoms (which may still be present when the angle of incidence is merely changed). FIG. 4 illustrates how surface implantation can modulate surface density through insertion and displacement effects. In some embodiments where a film including carbon is being formed, this can also modulate sp3 bond hybridization.

As seen in FIG. 4, surface implantation can be complicated by several mechanisms, including sputter etching, penetration of the surface energy barrier and ion reflection. A process energy window can be estimated from calculation estimates of these effects. For the case of a carbon implanted in a carbon or hydrocarbon substrate surface, size effects effectively determine the minimum energy for penetration; this is estimated from estimates of collision cross-sections to be about 20 to 25 eV. This is close to typical atomic displacement energies that correspond to the high energy tail of ion beam deposition (IBD) sputter deposition techniques. From a study of possible surface atom ejection mechanisms, a maximum arrival energy, for example from normal incidence, can be calculated to avoid excessive sputtering of the growing film and compared to predictions based on the energy dependence of the sputter coefficient. Sputtering, in part defines the upper energy limit (in certain embodiments) for the surface sub-plantation (SSP) technique. Both models predict minimal atomic ejection below about 40 to 42 eV. Practically, predictions from the energy dependence of the sputter yield indicate only about 10% surface sputter loss at about 60 eV, setting an effective “zero” sputter loss estimate for the upper process limit in some embodiments. In other embodiments, greater sputter losses may be tolerated or even desired, e.g., approximately 30-40% at implant energies of 80 eV in this example. It should be noted that the specific values discussed above apply onto the case of carbon; however the considerations apply to implantation of any material.

Disclosed methods and systems can advantageously provide a controlled low energy, mass filtered, charge ratio controlled, collimated beam particle source with appropriate beam current for goniokinematic processing techniques, such as those disclosed in U.S. patent application Ser. No. 13/440,068 entitled “METHODS OF FORMING LAYERS” filed on Apr. 5, 2012; Ser. No. 13/440,071 entitled “METHODS OF FORMING ALYERS” filed on Apr. 5, 2012; and Ser. No. 13/440,073 entitled “METHODS OF FORMING LAYERS” filed on Apr. 5, 2012, the disclosures of which are incorporated herein by reference thereto. Furthermore, methods and systems disclosed herein may be advantageous, for example, for driving surface collisional processes to enable controlled nanoengineering of surfaces, interfaces and near surface regions. Uses could include e.g. doping, defect formation, etch, stress control, sp3/sp2 ratio engineering and interfacial engineering.

Goniokinematic processes can utilize coordinated real time variation of particle beam parameters with the goniometric disposition of the target process surface (with respect to the beam axis). Such methods can e.g. help selectively control whether incident particles interrogate surface or sub-surface atoms and thereby interact with target atoms or atom “chains” through a surface interatomic potential or internal “bulk” interatomic potential or both. This in turn may determine whether a desired surface collision or surface collision sequence is achieved, whether a potential barrier to a surface reaction is overcome, or whether sub-surface penetration is achieved. For example, a particular profile of incident particle energies correlated to a select value or range of impact angles may be used to control a depth profile of implanted atoms e.g. in a doping concentration profile or e.g. an sp3/sp2 depth profile or to control a surface etch process. In goniokinematic processing, process control variables may be varied according to a process control algorithm to control the variation of, e.g. particle beam parameters (e.g. energy, beam particle density etc.) with respect to the geometric disposition of the substrate with the particle beam axis (e.g. tilt or polar angle, etc.) or vice versa.

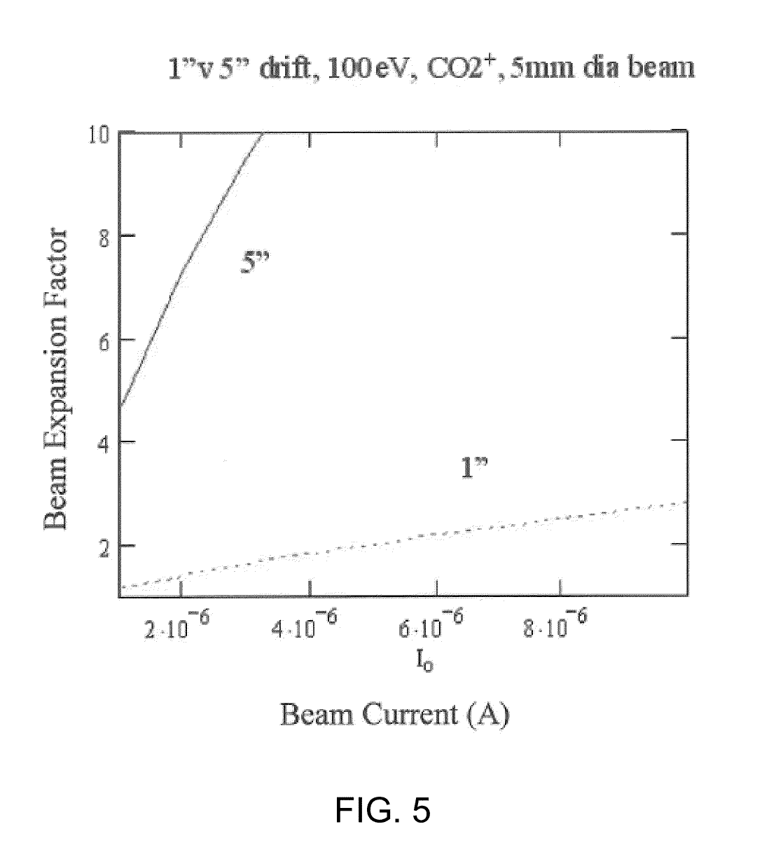

Narrow ion beams are typically electrostatically scanned over a substrate surface to produce a uniform ion dose. This can result in position variable angular registration of incoming ions with target atoms and therefore variations in collision kinematics, even for a fixed substrate position and atomically smooth surface. Furthermore, beam scanning can produce positional incident energy, kinematical energy exchange variation and positionally variable beam current densities even for fixed values of beam energy and beam ion current at the ion source on static substrates. Many of these effects also apply to scanned neutral particle beams. Mechanical scanning techniques combined with beam shaping methods can ameliorate several potential goniokinematic process variation effects created by scanning of spot particle beams. Examples include a particle beam formed into a thin “slot” like a profile of uniform intensity and a substrate scanned in a vertical or horizontal axis with respect to the beam axis to achieve overall uniform illumination over the substrate area. Some scan systems may use shaped static beam profiles combined with a high speed azimuthal rotation of the substrate in conjunction with a slower lateral or longitudinal scan motion to achieve a uniform field of particle irradiation over the substrate area. Such techniques can allow constant incident areal particle density processing over the substrate field in contrast to beam scanning techniques even if the substrate is tilted. In low energy nanoengineering ion beam processing, space-charge effects are particularly exacerbated. An example of the beam expansion produced for a molecular ion is shown FIG. 5 for given field free beam drift lengths and beam currents. The variation in length of field free drift path (FFDP) produced by beam scanning alters not just the particle incidence angle but also could cause considerable alteration to the incidence beam divergence (through variable path length and space-charge effects) affecting critical goniokinematic process variables which are also inconsistent across the materials process plane. This can be further compounded by a positionally variable areal particle density (at constant beam current). These effects can be ameliorated to some extent by static, shaped, particle beams using substrate motion designed to allow goniometrically variable processing of the substrate at constant FFDP and incident particle areal density. However, low, possibly impractically low beam current densities and geometric limitations resulting from the short FFDP could constrain commercial applications of low energy ion beam processing. Disclosed methods and systems can provide low energy neutral beam particle processing that does not suffer from these space-charged induced limitations and may be key to viable low energy particle processing at viable beam particle (flux) densities.

Disclosed methods and processes may also minimize or limit “undesirable effects” of layer formation to the first few atomic layers from the surface. Methods and processes disclosed herein can be described as confining the interaction of process particles (those being implanted, deposited, or both) with the underlying sub-surface to only a few bond lengths from the surface. The “few bond lengths” continuously moves (towards the surface) as growth proceeds. Methods and processes disclosed herein can also be characterized as controlling the exchange or coupling of energy from the process particles (those being deposited) into the surface or near surface region so that the underlying material is not detrimentally affected.

Methods and processes disclosed herein can alternatively be characterized as enabling insertion of incident species into the surface layer of atoms to within 30 Å from the surface. In some embodiments, disclosed methods and processes can enable insertion of incident species into the surface layer of atoms to within 20 Å from the surface. In some embodiments, disclosed methods and processes can enable insertion of incident species into the surface layer of atoms to within 15 Å from the surface. In some embodiments, disclosed methods and processes can enable insertion of incident species into the surface layer of atoms to within 10 Å from the surface. The phrase “first few atomic layers from the surface” or a particular measurement (for example “within 30 Å from the surface”) from the surface are meant to refer to the top atomic layers of a near surface layer, those that are closest to the deposition/implantation surface.

Undesirable effects that can be avoided or minimized using disclosed methods and systems can include for example damage centers or more specifically displaced atoms; defect generation and recombination; vacancies and recoils; recoil mixing on a scale significant to the interface of the deposited layer with the sub-surface layer; thermal dissipation of kinetic energy from deposited ions which can anneal desired properties (for example sp3 centers in carbon containing films) from the layer; sputtering; incident particle reflection; heat generation; and implantation (and intrinsic) induced defects that can enhance thermal relaxation of localized induced strain by defect center migration which can anneal desired properties (for example sp3 centers in carbon containing layers) from the layer; and any combination thereof. Disclosed processes and methods can avoid or minimize such effects, can confine them to the first few atomic layers from the surface, or both.

Incident hyperthermal particles can penetrate the surface potential barrier through either insertion in sites between existing atoms and/or through displacing existing atoms with the production of a non-recombining recoiling atom to induce localized increase in atomic density. Local atomic reconfiguration and sp3 bond hybridization can occur to accommodate the presence of the non-equilibrium hyperthermal and displaced particles and the resulting induced localized distortion/strain. Disclosed methods can achieve this in a very thin layer contained within a few bond lengths of the surface. In addition, the energetics can be adjusted to try to minimize instantaneous recombination and the production of thermal energy which can act to annihilate or anneal out, respectively, the sp3 centers.

The implant energy of a particle can be selected (the maximum is selected) to restrict the particle projected range into the surface to less than a maximum of a few bond lengths. The implant energy of a particle can also be selected (the minimum is selected) to be at least sufficient to allow penetration of the surface energy barrier to allow incorporation of the particles into the surface. Because of the minimum energy selected (enough to allow penetration of the particle into the substrate), growth of the layer is not accomplished via typical nucleation growth mechanisms. The chosen range of implant particle energies being such that kinematic energy transfer to target atoms is either insufficient to produce displacement or, on average, to generally produce only one or two displacement reactions or sufficient to allow insertion into the surface or to distances within a few bond lengths from the surface.

Thus, embodiments of METHODS OF FORMING LAYERS are disclosed. The implementations described above and other implementations are within the scope of the following claims. One skilled in the art will appreciate that the present disclosure can be practiced with embodiments other than those disclosed. The disclosed embodiments are presented for purposes of illustration and not limitation.

What is claimed is:

1. A method of forming a layer, the method comprising:
providing a substrate having at least one surface adapted for deposition thereon;
providing a precursor ion beam, the precursor ion beam comprising ions;
neutralizing at least a portion of the ions of the precursor ion beam to form a neutral particle beam, the neutral particle beam comprising neutral particles; and
directing the neutral particle beam towards the surface of the substrate, wherein the neutral particles have implant energies of not greater than 100 eV, and the neutral particles of the particle beam form a layer on the substrate.

2. The method according to claim 1, wherein the step of neutralizing at least a portion of the ions of the precursor beam comprises directing the precursor particle beam towards a metal surface.

3. The method according to claim 1, wherein the step of neutralizing at least a portion of the ions of the precursor beam comprises directing the precursor ion beam towards an ion optic grid to form a modified precursor particle beam.

4. The method according to claim 3, wherein the ion optic grid comprises three separate grids with the third grid being electrically biased.

5. The method according to claim 3, further comprising directing the modified precursor particle beam towards a high aspect ratio grid.

6. The method according to claim 1, wherein the step of neutralizing at least a portion of the ions of the precursor beam comprises mass selection techniques to form a modified precursor particle beam.

7. The method according to claim 6, further comprising directing the modified precursor particle beam towards a high aspect ratio grid.

8. The method according to claim 7, wherein the high aspect ratio grid is electrically biased.

9. The method according to claim 1, wherein the particles comprise carbon.

10. A method of forming a layer, the method comprising:
providing a substrate having at least one surface adapted for deposition thereon;
providing a precursor ion beam, the precursor ion beam comprising ions;
neutralizing at least a portion of the ions of the precursor ion beam to form a modified precursor particle beam by directing the precursor ion beam towards an ion optic grid; and
directing the modified precursor particle beam towards a high aspect ratio grid to form a neutral particle beam; and
directing the neutral particle beam towards the surface of the substrate,
wherein the neutral particles have implant energies of not greater than 100 eV, and the neutral particles of the particle beam form a layer on the substrate.

11. The method according to claim 10, wherein the high aspect ratio grid is electrically biased.

12. The method according to claim 10, wherein the particles comprise carbon.

13. The method according to claim 10 further comprising directing the precursor ion beam towards an accel-decel module and/or beam shaping module before directing it towards the high aspect ratio grid.

14. The method according to claim 10, wherein at least about 95% of the ions of the precursor particle beam are neutralized to form the neutral particle beam.

15. A method of forming a layer, the method comprising:
providing a substrate having at least one surface adapted for deposition thereon;
providing a precursor ion beam, the precursor ion beam comprising ions;
directing the precursor ion beam towards mass selection techniques to form a modified precursor particle beam; and
directing the modified precursor particle beam towards a high aspect ratio grid to form a neutral particle beam; and
directing the neutral particle beam towards the surface of the substrate,
wherein the neutral particles have implant energies of not greater than 100 eV, and the neutral particles of the particle beam form a layer on the substrate.

16. The method according to claim 15, wherein the ion source is a narrow beam ion source.

17. The method according to claim 15, wherein the high aspect ratio grid is electrically biased.

18. The method according to claim 15, wherein both the ions of the precursor ion beam and the neutral particles of the neutral particle beam have implant energies of not greater than about 100 eV.

19. The method according to claim 15, wherein at least about 95% of the ions of the precursor particle beam are neutralized to form the neutral particle beam.

20. The method according to claim 15, wherein the particles comprise carbon.
